(19) United States
(12) Patent Application Publication
(10) Pub. No.: US 2003/0000469 A1
(43) Pub. Date: Jan. 2, 2003

(54) Chemical enhancer treatment chamber and a Cu, thin film deposition apparatus of a semiconductor device using the same

(76) Inventor: Sung Gyu Pyo, Kyonggi-do (KR)

Correspondence Address: BIRCH STEWART KOLASCH & BIRCH, PO BOX 747, FALLS CHURCH, VA, 22040-0747, US

(21) Appl. No.: 10/162,873

(22) Filed: Jun. 6, 2002

(30) Foreign Application Priority Data
Jun. 12, 2001 (KR) P2001-32908

(51) Int. Cl. C23C 16/00

(52) U.S. Cl. 118/715

(57) ABSTRACT

A chemical enhancer (CE) treatment chamber and a Cu thin film deposition apparatus for a semiconductor device, wherein the CE treatment chamber includes a CE supplying line, a gas supplying line attached to the surface of the CE supplying line, a first showerhead connected to the CE supplying line and the gas supplying line, a second showerhead attached on a lower portion of the first showerhead, a showerhead injector attached to the lower portion of the second showerhead, a nozzle attached on a lower portion of the showerhead injector, having a plurality of holes, an edge beta sealing device, a heating device attached to the lower portion of the wafer, and a motion compensator for minimizing a gap formed between the first and second showerheads and the wafer due to the motions of the first and second showerheads.

### BACKGROUND OF THE INVENTION

1. Field of the Invention

The present invention relates to a deposition apparatus of a semiconductor device, and more particularly, to a chemical enhancer (CE) treatment chamber and a Cu thin film deposition apparatus of a semiconductor device using the same, in which throughput improves and reduces contamination of the chamber when catalysis treatment and CVD Cu deposition are carried out in one chamber.

2. Background of the Related Art

With the enhanced performance of semiconductor memory devices, increase in speed and reliability of a semiconductor device is becoming a major concern. Especially, the current Cu lining, which is used to increase speed and reliability of the semiconductor devices, uses electroplating as a deposition method.

However, the electroplating method requires a thin film deposition process of a clean and safe Cu seed layer, and so the electroplating method depends highly on the seed layer and may face its limitations in a Tech level of 0.1 μm.

Therefore, due to a rapid enhancement of semiconductor devices, it is advantageous to use a metal organic chemical vapor deposition (MOCVD) process in Cu line structures of advanced generation semiconductor devices, whereby a decrease in contact size and rapid increase in aspect ratio are expected.

However, the related art of Cu film deposition equipment has the following disadvantages.

In the case where the Cu thin film is deposited by the MOCVD process, a problem arises in that is not commercially used due to its low deposition speed. Additionally, further problems arise in that adhesion and texture quality are not good, thereby resulting in a major disadvantage in cost when compared to the electroplating process.

On the other hand, when a metallic thin film is deposited by the MOCVD process, chemical additives such as catalysts can be added to increase deposition speed and enhance basic characteristics of the metallic thin film. However, a problem arises in that no CVD equipment cluster is provided, in which in-situ process carried out after barrier deposition and a catalyst enabling plasma treatment is used.

### SUMMARY OF THE INVENTION

Accordingly, the present invention is directed to a CE treatment chamber and Cu thin film deposition apparatus of a semiconductor using the same that substantially obviates one or more problems due to the limitations and disadvantages of the related art.

Accordingly, an object of the present invention is to provide a CE treatment chamber, wherein a chamber carries out catalysis treatment and plasma treatment and, at the same time, removes residue produced from the surface of a Cu thin film after the deposition of the Cu thin film, through plasma treatment.

Another object of the present invention is to provide a Cu thin film deposition apparatus of a semiconductor device using the aforementioned CE treatment chamber.

Additional advantages, objects, and features of the present invention will be set forth in part in the description which follows and in part will become apparent to those ordinary skill in the art upon examination of the following or may be learned from practice of the invention. The objectives and other advantages of the invention may be realized and attained by the structure particularly pointed out in the written description and claims hereof as well as the appended drawings.

To achieve these objectives and other advantages and in accordance with the purpose of the present invention, as embodied and broadly described herein, a CE treatment chamber is provided which includes a CE supplying line for sending out CE through a liquid vaporizer, a gas supplying line attached to the surface of the CE supplying line for sending out vaporized gas, a first showerhead connected to the CE supply line and the gas supply line, for primarily equalizing the CE, a second showerhead attached to the lower portion of the first showerhead, secondarily equalizing the primary equalized CE, a showerhead injector attached to the lower portion of the second showerhead, injecting the secondarily equalized CE, a nozzle attached on the lower portion of the showerhead injector, having a plurality of holes needed to supply the primary and secondarily equalized CE to a wafer, an edge beta sealing device for sealing the CE supplied from the nozzle onto the wafer and preventing the CE from being deposited on the edge of the wafer to avoid further contamination, a heating device attached on a lower portion of the wafer for heating the wafer, and a motion compensator for minimizing the gas formed between the first and second showerheads and the wafer due to motions of the first and second showerheads.

In another aspect of the present invention, a Cu thin film deposition apparatus of a semiconductor device includes a load lock for carrying out the steps before and after wafer processing, an aligner for carrying out alignment so that the wafer reaches a desired position, a degas chamber for removing residue such as gas produced on the surface of the wafer, a feeding chamber provided with a robot for moving the wafer into and out of each chamber, as pre-cleaning chamber for cleaning the inside and the outside of a pattern using plasma on the wafer fed by the feeding chamber, a barrier metal deposition chamber for depositing barrier metal on the pre-cleaned wafer, a CE treatment chamber for providing an equal CE treatment before depositing the Cu thin film on the barrier metal, a CVD Cu deposition chamber for depositing the Cu thin film on the barrier metal, a plasma treatment chamber for carrying out plasma treatment for achieving a uniform Cu thin film deposition after the CE treatment by the CE treatment chamber and the step of removing residue such as CE produced on the surface of the Cu thin film.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 illustrates a CE treatment chamber according to the present invention;

FIG. 2A illustrates a CE treatment chamber according to the present invention, prior to CE treatment;

FIG. 2B illustrates a CE treatment chamber according to the present invention during CE treatment; and

FIG. 3 illustrates a Cu thin film deposition system of a semiconductor device using the CE treatment chamber of the present invention.

### DETAILED DESCRIPTION OF THE PREFERRED EMBODIMENTS

Reference will now be made in detail to the preferred embodiments of the present invention, examples of which are illustrated in the accompanying drawings.

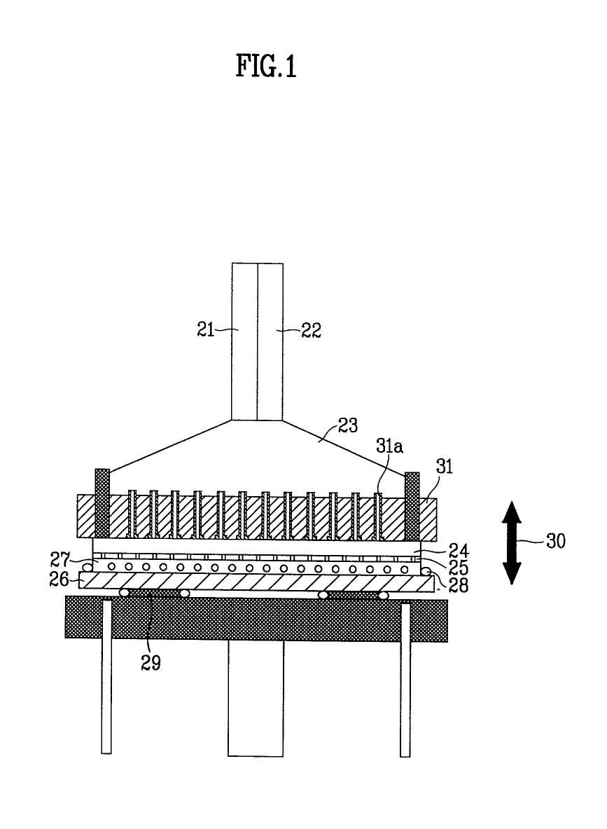

FIG. 1 illustrates the CE treatment chamber according to the present invention.

As shown in FIG. 1, the CE treatment chamber includes a CE supply line 21 sending out CE through a liquid vaporizer of either a liquid delivery system (LDS) or a bubbler type, a gas supply line 22 attached on a surface of the CE supply line 21, sending out a vaporized gas with a flux of 1 to 5000 sccm, such as HE, H₂, and Ar, a first showerhead 23 connected to the CE supply line 21, primarily equalizing the CE, a second showerhead 24 attached to the lower portion of the first showerhead 23, secondarily equalizing the primarily equalized CE, a showerhead injector 25 attached to the lower portion of the second showeread 24 for injecting the secondarily equalized CE, a nozzle 27 attached to the lower portion of the showerhead injector 25, having a plurality of holes of 0.1 to 5 mm in diameter formed at set intervals, which are needed to supply the primarily and secondarily equalized CE to a wafer 26, an edge beta sealing device 28, which can be controlled from 1 to 10 mm for sealing the CE supplied from the nozzle 27 onto an entire surface of the wafer 26 and preventing the CE from being deposited on an edge of the wafer 26 to avoid further contamination, a heating device 29 attached to the lower portion of the wafer 26 for heating the wafer 26, and a motion compensator 30 for controlling the gap from 1 to 50 mm which is formed between the first and second showerheads 23 and 24 and the wafer 26 due to the motions of the first and second showerheads.

In case, a supply line 31 is additionally formed between the first showerhead 23 and the second showerhead 24 to send equalized CE to the second showerhead 24. The additional supplying line 31 is provided with a plurality of through holes 31a of 0.1 to 3 in diameter formed on a metallic substrate. The through holes 31a are formed in quadratic shapes and at regular intervals.

The CE is a substance containing I, such as CH₂I₂, CH₃I, or C₂H₅I, or elements of the 7^{th} group of the Periodic Table of elements, such as F, Cl, I, or Br.

The operation of the aforementioned CE treatment chamber according to the present invention now be described.

First, when the wafer 26 is inserted into the CE treatment chamber of the present invention, the heating device 29 moves so that the wafer 26 reaches an edge beta sealing device 28, thereby beginning the CE treatment process.

In other words, the CE, which is sent through either a liquid vaporizer of a liquid delivery system (LDS) or a bubbler, is supplied to the wafer, sealed in the edge beta sealing device 28, by passing through the CE supplying line 21 to the first showerhead 23. The CE is then primarily equalized at the showerhead and then passes through through holes 31a of the supplying line 31 to reach the second showerhead 24 where it is secondarily equalized.

Afterwards, the CE equalized, in the second showerhead 24, is set through a nozzle 27, having a plurality of holes formed at a constant interval, in order to be equally injected onto the wafer.

The edge beta sealing device 28 blocks the injected CE, which the flows out through the nozzle 27. The edge beta sealing device 28 controls the CE so as not to learn toward the edge of the wafer 26, thereby preventing CE from being absorbed on unnecessary portions of the wafer. Accordingly, in a later process, excessive Cu deposition or contamination can be avoided.

In addition, when the CE treatment is completed, vaporized gas such as He, H₂, or Ar, which is supplied by the gas supplying line 22, purifies the first showerhead 23, the second showerhead 24, the wafer 26, and the edge beta sealing device 28. Also, any CE that is incompletely absorbed on the wafer 26 is removed and sent out through the nozzle 27.

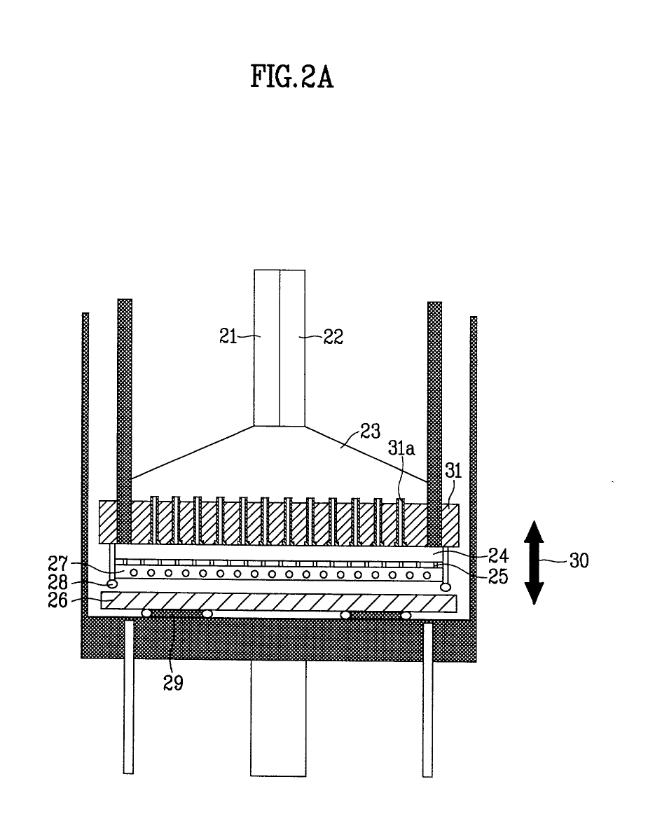

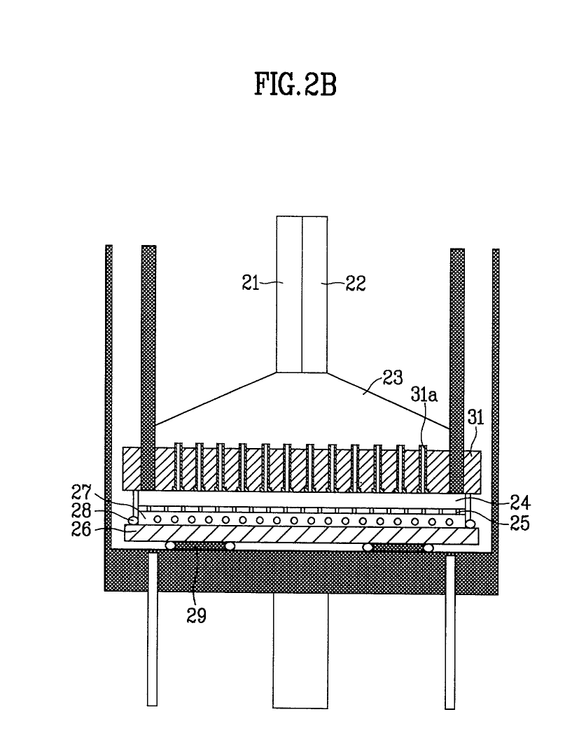

FIG. 2A illustrates a CE treatment chamber according to the present invention before CE treatment, and FIG. 2B illustrates the CE treatment chamber according to the present invention during CE treatment.

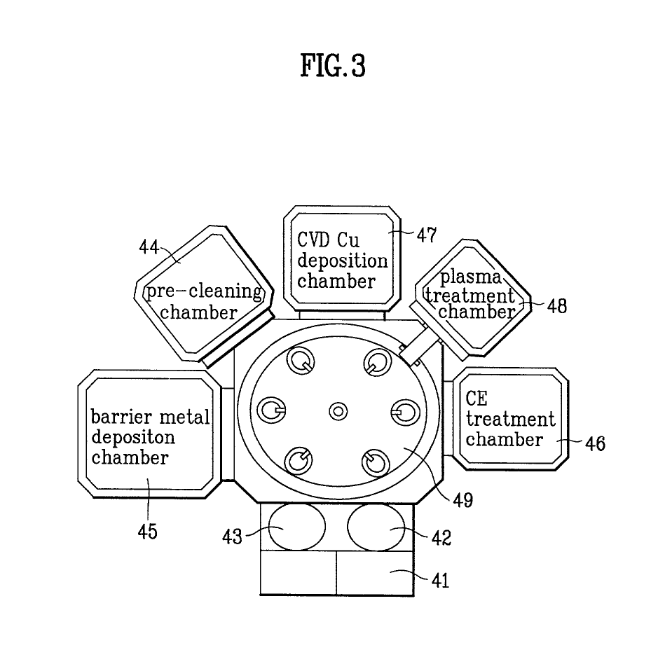

FIG. 3 illustrates Cu thin film deposition equipment of a semiconductor device using the CE treatment chamber of the present invention.

As shown in FIG. 3, the Cu thin film deposition equipment of the semiconductor device includes a load lock 41, an aligner 42, a degas chamber 43, a pre-cleaning chamber 44, a barrier metal deposition chamber 45, a CE treatment chamber 46, a CVD Cu deposition chamber 47, a plasma treatment chamber 48, and a feeding chamber 49.

In other words, a system for super-filling is needed, which includes a chamber for carrying out CE treatment and plasma treatment for equal Cu deposition during a CECVD Cu deposition process and another chamber removing, through plasma treatment, CE residue produced from the surface of a CECVD Cu thin film after the deposition of the CECVD Cu thin film. The corresponding structure of the equipment and its detailed wafer flow will now be described.

As shown in FIG. 3, Cu thin film deposition equipment of a semiconductor device includes a load lock 41 for carrying out the steps before and after wafer (not shown) processes, an aligner 42 for carrying out alignment so that the wafer reaches a desired position, a degas chamber 43 for removing residue such as gas produced on a surface of the wafer, a feeding chamber 49 provided with a robot for positioning the wafer in/out of each chamber, a pre-cleaning 44 for cleaning the inside and the outside of a pattern using plasma on the wafer fed by the feeding chamber 49, a barrier metal deposition chamber 45 for depositing barrier metal on the pre-cleaned wafer by PVD, CVD, or ALD processes, a CE treatment chamber 46 for an equal CE treatment before depositing the Cu thin film on the barrier metal, a CVD Cu deposition chamber 47 for depositing the Cu thin film on the barrier metal, and a plasma treatment chamber 48 for carrying out plasma treatment for the uniform Cu thin film deposition after the CE treatment by the CE treatment chamber 46 and removing the residue such as CE produced on the surface of the Cu thin film after the deposition of the CVD Cu thin film.

The operation of the Cu thin film deposition system of a semiconductor device using the CE treatment chamber according to the present invention will now be described.

First, a wafer is introduced into a chamber through a load lock 41, and an aligner 42 aligns the wafer to a desired position. Then, residue produced on the surface of the wafer is removed in a degas chamber 43.

Subsequently, the wafer is introduced to a pre-cleaning chamber 44 through chamber 49. A pre-cleaning process is then carried out on an entire surface of the wafer by a dual frequency etch (DFE) process using Ar or He, or by a reactive cleaning process using a gas such as a halogen.

Then, the pre-cleaned wafer is fed into a barrier metal deposition chamber 45 through the feeding chamber 49, and barrier metal is deposited on the entire surface of the wafer using a PVD process, an ionized PVD process, a CVD process, or an atomic layer deposition (ALD) process.

In this case, Ta, TaN, WNx, TiN, TiAlN, TaSiN, or TiSiN is used as the barrier metal.

Afterwards, the wafer containing the barrier metal is introduced to the plasma treatment chamber 48 through the feeding chamber 49 to remove, through plasma treatment, residue produced on the surface of the barrier metal and, at the same time, to equalize the surface of the metal.

Subsequently, the wafer is fed to the CE treatment chamber 46 through the feeding chamber 49 to equally adsorb CE on the entire surface of the wafer. Then, the wafer equally absorbed with CE is fed into the CVD Cu deposition chamber 47 through the feeding chamber 49 to deposit the Cu thin film on the barrier metal.

In this situation, the CE treatment chamber 46 consists of a chamber whereby CE treatment is carried out by using direct injection, spin coating, or a showerhead method. When a Cu thin film is deposited using the CVD Cu deposition chamber 47, the barrier metal is deposited and then plasma treatment is carried out using the plasma treatment chamber 48.

In addition, by setting an AGL flash Cu deposition chamber, which deposits flash Cu as an AGL enhance adhesion of the CVD Cu thin film, deposited can be carried out at a thickness of 10 to 500 Å. The AGL flash Cu deposition chamber has a power of 1 to 500, in which deposition can be carried out by a long throw, PVD, or ionized PVD at a temperature ranging from 50 to 300° C.

Furthermore, the wafer deposited with the Cu thin film is sent through the feeding chamber 49 into the plasma treatment chamber 48. Then, the CE used to deposit the Cu thin film and residue produced on the surface are removed by the plasma treatment, and the wafer is fed through the feeding chamber 49 and output to the load lock 41.

The aforementioned CE treatment chamber and the Cu thin film deposition equipment for a semiconductor device using the same have the following advantages.

The CE treatment can be carried out equally on the entire surface of the wafer; incompletely adsorbed CE can be removed, chamber contamination can be minimized; and diversion to the edge of the wafer can be controlled, thereby preventing excessive Cu deposition or contamination from occurring in a later process.

In addition, with the plasma treatment, super-filling of the Cu thin film can be processed equally and CE produced on the surface of the Cu thin film can be effectively removed.

The foregoing embodiments are merely exemplary and are not to be construed as limiting the scope of the present invention as defined by the claims. Thus, the present invention can be readily applied to other types of systems. Thus, many alternatives, modifications, and variations will be apparent to those skilled in the art from the present detailed description.

What is claimed is:

1. A chemical enhancer (CE) treatment chamber comprising:
a CE supply line for introducing CE through a liquid vaporizer;
a gas supply line attached to the surface of the CE supplying line for sending out vaporized gas;
a first showerhead connected to the CE supply line and the gas supply line for primarily equalizing the CE;
a second showerhead attached to the lower portion of the first showerhead for secondarily equalizing the primarily equalized CE;
a showerhead injector attached to the lower portion of the second showerhead, injecting the secondarily equalized CE;
a nozzle attached to the lower portion of the showerhead injector and containing a plurality of holes for supplying the primarily and secondarily equalized CE to a wafer;
an edge beta sealing device for sealing the CE supplied from the nozzle onto the wafer and preventing the CE from being deposited at the edge of the wafer to avoid further contamination;
a heating device attached on a lower portion of the wafer for heating the wafer; and
a motion compensator for minimizing a gap formed between the first and second showerheads and the wafer due to the motions of the first and second showerheads.

2. The CE treatment chamber according to claim 1, further comprising a supplying line provided between the first showerhead and the second showerhead, said supply line having a plurality of through holes formed on a metallic substrate, for conveying the CE primarily equalized at the first showerhead to the second showerhead.

3. The CE treatment chamber according to claim 2, wherein the through holes are formed in quadrate shapes and at regular intervals.

4. The CE treatment chamber according to claim 1, wherein the vaporized gas comprises He, H₂, or Ar.

5. The CE treatment chamber according to claim 1, wherein the CE consists of a substance containing I.

6. The CE treatment chamber of claim 5, wherein the I-containing substance is selected from the group consisting of CH₂I, CH₃I, C₂H₅I and mixtures thereof.

7. The CE treatment chamber according to claim 1, wherein the CE containes elements of the 7^{th} group of the Periodic Table.

8. The CE treatment chamber of claim 7, wherein the elements of the 7^{th} group of the Periodic Table are selected from the group consisting of F, Cl, I, Br and mixtures thereof.

9. The CE treatment chamber according to claim 1, wherein the liquid vaporized is either a liquid delivery system (LDS) or a bubbler type.

10. The CE treatment chamber according to claim 1, wherein the vaporized gas has a flux of 1 to 5000 sccm.

11. The CE treatment chamber according to claim 1, wherein the showerhead injector is provided with a plurality of holes of 0.1 to 3 mm in diameter formed at a set interval.

12. The CE treatment chamber according to claim 1, wherein the motion compensator controls the gap which is formed between the first and second showerheads and the wafer, which varies from 1 to 50 mm.

13. The CE treatment chamber according to claim 1, wherein the holes of the nozzle are of 0.1 to 5 mm in diameter.

14. A Cu thin film deposition apparatus for a semiconductor device comprising:
a load lock for carrying out the steps before and after wafer processing;
an aligner for carrying out alignment so that the wafer reaches a desired position;
a degas chamber for removing residue such as gas produced on a surface of the wafer;
a feeding chamber provided with a robot for moving the wafer into and out of each chamber;
a pre-cleaning chamber for cleaning the inside and the outside of a pattern using plasma on the wafer fed by the feeding chamber;
a barrier metal deposition chamber for depositing barrier metal on the pre-cleaned wafer;
a CE treatment chamber for providing an equal CE treatment before depositing a Cu thin film on the barrier metal;
a CVD Cu deposition chamber for depositing Cu thin film on the barrier metal; and
a plasma treatment chamber for carrying out plasma treatment for providing a uniform Cu thin film deposition after a CE treatment by the CE treatment chamber and for removing residue such as CE produced on the surface of the Cu thin film.

15. The apparatus according to claim 14, wherein the pre-cleaning chamber carries out a pre-cleaning process by a dual frequency etch (DFE) using Ar or He, or by a reactive cleaning process using a gas such as a halogen.

16. The apparatus according to claim 14, wherein the barrier metal deposition chamber carries out a deposition process using a PVD process, an ionized PVD process, a CVD process, or an ALD process.

17. The apparatus according to claim 14, wherein the barrier metal is selected from the group consisting of Ta, TaN, WNx, TiN, TiAlN, TaSiN, and TiSiN.

18. The apparatus according to claim 14, wherein the CVD Cu thin film deposition chamber carries out the deposition process at a temperature of from 50 to 300° C.

19. The apparatus according to claim 14, wherein the CE treatment chamber carries out the CE treatment using direct injection, spin coating, or the showerhead method.
